(19) United States
(12) Patent Application Publication
(10) Pub. No.: US 2010/0307576 A1
(43) Pub. Date: Dec. 9, 2010

(54) Photovoltaic device and method for manufacturing the same

(75) Inventors: Chiung-Wei Lin, Taipei City (TW); Yi-Liang Chen, Taipei City (TW)

Correspondence Address: BACON & THOMAS, PLLC, 625 SLATERS LANE, FOURTH FLOOR, ALEXANDRIA, VA, 22314-1176, US

(73) Assignees: Tatung University, Taipei (TW); Tatung Company, Taipei (TW)

(21) Appl. No.: 12/588,127

(22) Filed: Oct. 6, 2009

(30) Foreign Application Priority Data
Jun. 8, 2009 (TW) 098119015

(51) Int. Cl. H01L 31/0216; H01L 31/18

(52) U.S. Cl. 136/256; 438/72; 257/E31.119

(57) ABSTRACT

The present invention relates to a photovoltaic device and a method for manufacturing the same. The photovoltaic device includes: a first semiconductor layer; a second semiconductor layer, disposed on the first semiconductor layer; a first electrode layer, connected to the first semiconductor layer; a second electrode layer, connected to the second semiconductor layer, in which the second electrode layer has an open area to expose the second semiconductor layer; and a low reflective conductive film, disposed in the open area and connected to the second electrode layer and the second semiconductor layer, in which the resistivity of the low reflective conductive film is less than or equal to that of the second semiconductor layer. Accordingly, the photovoltaic device provided by the present invention exhibits effectively reduced parasitic series resistance effect and thereby improved photoelectric conversion efficiency.

### BACKGROUND OF THE INVENTION

1. Field of the Invention

The present invention relates to a photovoltaic device and a method for manufacturing the same and, more particularly, to a photovoltaic device, which can reduce parasitic series resistance effect and thereby improve photoelectric conversion efficiency, and a method for manufacturing the same.

2. Description of Related Art

Due to the finite nature of conventional energy such as petroleum and coal, alternative forms of energy have been developed to replace the conventional energy. Among all the forms of alternative energy, solar energy is one of the abundant and environmentally friendly, so research about solar cells have been vigorously investigated. The solar cell is a photovoltaic device to convert light into electricity. The most common known solar cell is configured as a p-n junction, which is formed by joining p-type and n-type semiconductors together in very close contact. After the p-n junction absorbs light and separates electrons and holes, the electric field opposes the obtained electrons and holes moving to the n-type and p-type semiconductors respectively to contribute current. Finally, the current is derived out through electrodes to form electricity for usage or storage.

FIG. 1 shows a basic structure of a conventional solar cell. As shown in FIG. 1A, the convention solar cell mainly comprises: a p-type semiconductor layer 11; an n-type semiconductor layer 12, disposed on the p-type semiconductor layer 11; a first electrode layer 13, connected to the p-type semiconductor layer 11; and a second electrode layer 14, connected to the n-type semiconductor layer 12, wherein the second electrode layer 14 provided at the light incident surface has an open area 141. Herein, the second electrode layer 14 is in an interdigitated form (U-shape), in order to increase the light incident area. In addition, in order to increase the amount of light extraction, an anti-reflective layer 15 is disposed in the open area 141 of the second electrode layer 14 to reduce the reflection of the incident light. However, the interdigitated electrodes cause the increase on the parasitic series resistance effect of the solar cell and thereby decrease the photoelectric conversion efficiency thereof.

Hence, a suggestion of using a transparent conductor (such as ITO) as an electrode provided at the light incident surface has been proposed. The electrode provided at the light incident surface is made of transparent material, so the electrode can form on the entire surface of the semiconductor layer, and the shape of the electrode does not have to be designed in an interdigitated form. Furthermore, FIG. 1B is a perspective view of another conventional solar cell. As shown in FIG. 1B, the configuration of the conventional solar cell is almost the same as that of the solar cell represented in FIG. 1A, except that a transparent conductor 16 is disposed between the second electrode layer 14 and the n-type semiconductor layer 12, in order to increase the conductivity.

In addition, FIG. 1C is a perspective view of another conventional solar cell. As shown in FIG. 1C, the configuration of the conventional solar cell is almost the same as that of the solar cell represented in FIG. 1B, except that there is no anti-reflective layer disposed in the open area 141 of the second electrode layer 14.

In conclusion, two methods have been proposed in the art for improving the photoelectric conversion efficiency of the solar cells. One method is that a transparent conductor is used as an electrode, which is formed on the entire surface of a semiconductor layer, so the shape of the electrode does not have to be designed in an interdigitated form. The other method is that a transparent conductor is formed between the electrode and the semiconductor layer to increase the conductivity. However, whether the aforementioned transparent conductor is formed between the electrode and the semiconductor, or formed directly on the semiconductor to serve as an electrode, the resistance of the transparent conductor is still too large, so the photoelectric conversion efficiency cannot be improved greatly. Furthermore, according to the solar cells with the aforementioned configurations, the interface potential barrier between different materials is raised due to the resistance of the transparent conductor, which causes the decrease on the photoelectric conversion efficiency of the solar cells.

### SUMMARY OF THE INVENTION

The object of the present invention is to provide a photovoltaic device, which can reduce parasitic series resistance effect. Also, the material of an electrode provided at the light incident surface is not limited to a transparent material. Hence, a material, which is able to derive effective charge carriers effectively, can be used for improving the photoelectric conversion efficiency of the photovoltaic device greatly.

To achieve the object, the photovoltaic device of the present invention comprises: a first semiconductor layer; a second semiconductor layer, disposed on the first semiconductor layer; a first electrode layer, connected to the first semiconductor layer; a second electrode layer, connected to the second semiconductor layer, wherein the second electrode layer has an open area to expose the second semiconductor layer; and a low reflective conductive film, disposed in the open area and connected to the second electrode layer and the second semiconductor layer. In order to increase the conductivity of the open area and reduce the parasitic series resistance effect, the resistivity of the low reflective conductive film is less than or equal to that of the second semiconductor layer.

According to the photovoltaic device of the present invention, the conductivity of the open area is increased by forming the low reflective conductive film in the open area. Because light can incident into the open area, the material of the second electrode layer is not limited to a transparent material, and can be any kind of conventional materials which is suitable for preparing electrodes. Preferably, the material of the electrode can be made of a material which is able to derive effective charge carriers effectively, to increase the photoelectric conversion efficiency of the solar cell effectively. For example, the electrode can be an Ag electrode. In addition, the form of the second electrode layer of the present invention can be designed into any conventional configuration with open areas. For example, the form of the second electrode layer can be an interdigitated shape (U-shape), a strip shape, or a net shape.

The photovoltaic device of the present invention may further comprise an anti-reflective layer, which is disposed on the low reflective conductive layer. Herein, the anti-reflective layer can decrease the reflection of incident light, and thereby improve the amount of light extraction.

According to the photovoltaic device of the present invention, the low reflective conductive film can be any kind of conductive film with light transmittance, low reflection, and resistivity less than or equal to the second semiconductor layer. Preferably, the low reflective conductive film is a conductive film with high luminous transmittance, low reflection, and high conductivity. The examples of the low reflective conductive film can be a metal film, a metal oxide film, or a conductive nano-material film. Herein, the metal film can be an Al film, an Au film, an Ag film, a Cu film, a W film, a Cr film, or a Ni film. Preferably, the material of the metal film is the same as that of the second electrode film, in order to prevent repulsion between different materials. For example, the second electrode layer can be an Al electrode layer, and the metal film can be an Al film. In addition, the main material of the metal oxide film can be ZnO, SnO₂, ZnO—SnO₂, or ZnO—In₂O₃, and further comprise other elements. The example of the elements can be Al, Ga, In, B, Y, Sc, F, V, Si, Ge, Zr, Hf, N, Be, or a combination thereof. Preferably, the metal oxide film is an ITO film. In addition, the conductive nano-material film can be a conductive nano-tube film, a conductive nano-wire film, a conductive nano-belt film, a conductive nano-rod film, or a conductive nano-ball film, and further can be a non-metal nano-material film with conductivity, or a metal nano-material film. The example of the non-metal nano-material film can comprise a carbon nano-tube film, a conductive polymer fiber film, and the like; and the example of the metal nano-material film can comprise a metal element nano-material film, a metal alloy nano-material film, a metal compound nano-material film, and a metal oxide nano-material film. More preferably, the low reflective conductive film is a carbon nano-tube film, which has better anti-reflection to increase the amount of light extraction. Furthermore, the low reflective conductive film may also be disposed on the surface of the second electrode layer.

According to the photovoltaic device of the present invention, the first semiconductor layer can be a p-type semiconductor layer, and the second semiconductor layer can be an n-type semiconductor layer; or the first semiconductor layer can be an n-type semiconductor layer, and the second semiconductor layer can be a p-type semiconductor layer. The dopant of the p-type semiconductor can be elements from group III of the periodic table, and the dopant of the n-type semiconductor can be elements from group V of the periodic table.

According to the photovoltaic device of the present invention, the material of the first electrode layer is unlimited, and can be any kind of suitable electrode materials used in the art. Preferably, the material of the first electrode layer is a material with high work function, to form an ohmic contact layer. One example of the first electrode layer is an Al electrode.

According to the photovoltaic device of the present invention, the material of the second electrode layer is unlimited, and can be any kind of suitable electrode materials used in the art. Preferably, the material of the second electrode layer is a material with low work function, which can form an ohmic contact layer and also conduct effective charge carriers effectively to improve the photoelectric conversion efficiency effectively. One example of the first electrode layer is an Ag electrode.

According to the photovoltaic device of the present invention, preferably, the thickness of the low reflective conductive film can be in a range of 10 Å to 10 μm; the resistivity of the low reflective conductive film can be in a range of 10⁻³ Ωcm to 10⁻⁸ Ωcm; and the reflectivity of the low reflective conductive film can be less than 10%.

In addition, the present invention further provides a method for manufacturing the aforementioned photovoltaic device, which comprises: forming a second semiconductor layer on a first semiconductor layer; forming a first electrode layer on the first semiconductor layer, and forming a second electrode layer on the second semiconductor layer, wherein the second electrode layer has an open area to expose the second conductor layer; and forming a low reflective conductive film in the open area, to connect the low reflective conductive film to the second electrode layer and the second semiconductor layer, wherein the resistivity of the low reflective conductive film is less than or equal to that of the second semiconductor layer.

The method for manufacturing the photovoltaic device of the present invention may further comprise: forming an anti-reflective layer on the low reflective conductive film.

According to the method for manufacturing the photovoltaic device of the present invention, the low reflective conductive film may further form on a surface of the second electrode layer.

In conclusion, compared to the conventional method for improving the photoelectric conversion efficiency of the photovoltaic device, the parasitic series resistance effect in the open area can be reduced by using the low reflective conductive film in the photovoltaic device of the present invention. Hence, the form of the electrode provided at the light incident surface is unlimited, and can be in an interdigitated shape (U-shape), a strip shape, or a net shape. Also, the material of the electrode provided at the light incident surface is unlimited, and can be any kind of conventional electrode materials, which can conduct charge carriers effectively. For example, the electrode provided at the light incident surface can be an Ag electrode. Hence, compared to the conventional photovoltaic device using transparent conductor as an electrode, the photovoltaic device of the present invention can improve the photoelectric conversion efficiency more effectively. In addition, compared to the conventional photovoltaic device having a transparent conductor between the electrode and the semiconductor, there is no additional layers formed between the electrode and the semiconductor layer of the photovoltaic device of the present invention. Hence, when the photovoltaic device of the present invention is used, the problem of the decrease in the photoelectric conversion efficiency, which is caused by the increase in the interface potential barrier, can be solved.

### BRIEF DESCRIPTION OF THE DRAWINGS

FIG. 1A is a perspective view of a conventional solar cell;

FIG. 1B is a perspective view of another conventional solar cell;

FIG. 1C is a perspective view of further another conventional solar cell;

FIGS. 2A to 2C are perspective views showing the process of manufacturing a photovoltaic device in Embodiment 1 of the present invention;

FIG. 3 is a cross-sectional view of a photovoltaic device in Embodiment 4 of the present invention;

FIG. 4 is a cross-sectional view of a photovoltaic device in Embodiment 5 of the present invention;

FIG. 5 is a graph showing the relation between current and voltage of photovoltaic devices manufactured in Embodiment 1 and Comparative embodiment 1, wherein-▪-represents Embodiment 1, and-Δ-represents Comparative embodiment 1;

FIG. 6 is a graph showing the relation between power and voltage of photovoltaic devices manufactured in Embodiment 1 and Comparative embodiment 1, wherein-▪-represents Embodiment 1, and-Δ-represents Comparative embodiment 1; and

FIG. 7 is a graph showing the relation between voltage and short-circuit current of photovoltaic devices manufactured in Embodiment 4 and Comparative embodiment 2, wherein-▪-represents Embodiment 4, and-Δ-represents Comparative embodiment 2.

### DETAILED DESCRIPTION OF THE PREFERRED EMBODIMENT

Hereinbelow, the present invention will be described in detail with reference to the Embodiments. The present invention may, however, be embodied in many different forms and should not be construed as being limited to the Embodiments set forth herein. Rather, these Embodiments are provided to fully convey the concept of the invention to those skilled in the art.

### Embodiment 1

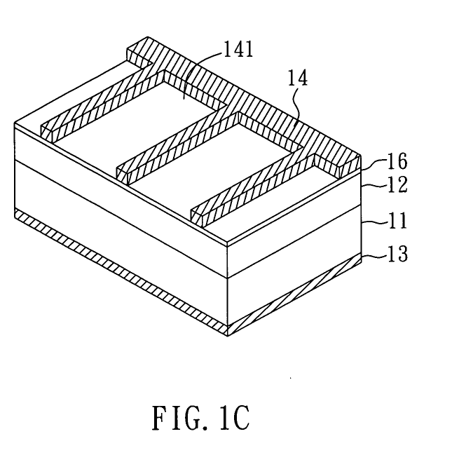

FIGS. 2A to 2C are perspective views showing the process of manufacturing a photovoltaic device in Embodiment 1 of the present invention. First, as shown in FIG. 2A, a second semiconductor layer 22 is formed on a first semiconductor layer 21. In the present embodiment, the first semiconductor layer 21 is a p-type silicon layer, and the second semiconductor layer 22 is an n-type silicon layer.

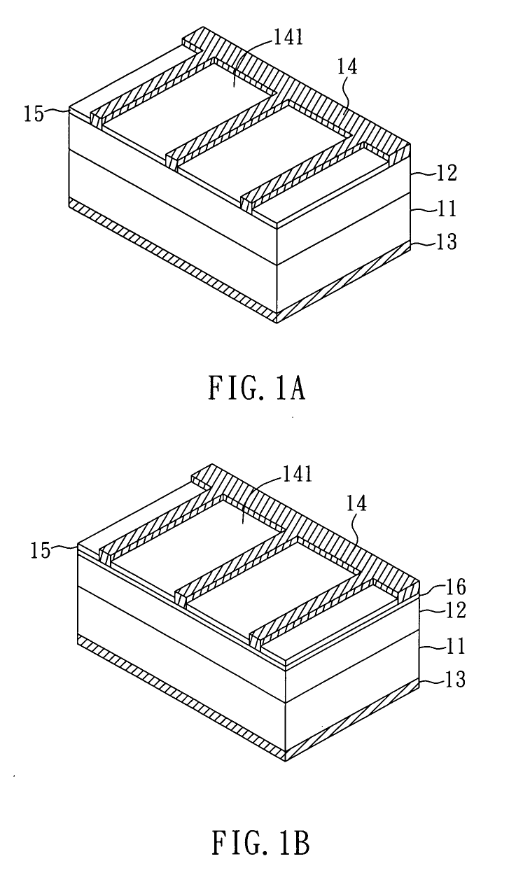

Then, as shown in FIG. 2B, a first electrode layer 23 is formed on the first semiconductor layer 21, and a second electrode layer 24 is formed on the second semiconductor layer. Herein, the second electrode layer 24 has an open area 241 to expose the second semiconductor layer 22. In the present embodiment, the second electrode layer 24 is in an interdigitated form, as shown in FIGS. 1A and 1B. Furthermore, the first electrode layer 23 contacting with the first semiconductor layer can be made of a material with high work function to form an ohmic contact layer; and the second electrode layer 24 contacting to the second semiconductor layer 22 can be made of a material with low work function to form an ohmic contact layer. In the present embodiment, the first electrode layer 23 is an Al electrode, and the second electrode layer 24 is an Ag electrode.

Then, as shown in FIG. 2C, a low reflective conductive film 25 is formed in the open area 241, wherein the low reflective conductive film 25 is connected to the second electrode layer 24 and the second semiconductor layer 22. In the present embodiment, the low reflective conductive film 25 is a carbon nano-tube film. The carbon nano-tube film is formed by dispersing carbon nano-tubes in volatile solvent, such as ethanol, isopropanol, and acetone, and followed by coating the carbon nano-tube solution in the open area 241 to form the carbon nano-tube film in the open area 241, wherein the carbon nano-tubes are arranged in a net-shape configuration. In the present invention, the carbon nano-tubes are dispersed in ethanol to form the carbon nano-tube solution. The carbon nano-tubes can be prepared by any conventional methods, such as an arc-discharge process, a laser ablation method, a chemical vapor deposition (CVD), a solar energy method, and a microwave enhanced plasma chemical vapor deposition (MEP-CVD). In the present embodiment, the carbon nano-tubes are prepared by an arc-discharge process.

As shown in FIG. 2C, the present embodiment provides a photovoltaic device, which comprises: a first semiconductor layer 21; a second semiconductor layer 22, disposed on the first semiconductor layer 21; a first electrode layer 23, connected to the first semiconductor layer 21; a second electrode layer 24, connected to the second semiconductor layer 22, wherein the second electrode layer 24 has an open area 241 to expose the second semiconductor layer 22; and a low reflective conductive film 25, disposed in the open area 241 and connected to the second electrode layer 24 and the second semiconductor layer 22, wherein the resistivity of the low reflective conductive film 25 is less than or equal to that of the second semiconductor layer 22.

### Embodiment 2

The photovoltaic device of the present invention is the same as that of Embodiment 1, except that the low reflective conductive film 25 of the present embodiment is an Ag film.

### Embodiment 3

The photovoltaic device of the present invention is the same as that of Embodiment 1, except that the low reflective conductive film 25 of the present embodiment is an Al film.

### Embodiment 4

The photovoltaic device of the present invention is the same as that of Embodiment 1, except that the low reflective conductive film 25 of the present embodiment is an ITO film.

### Embodiment 5

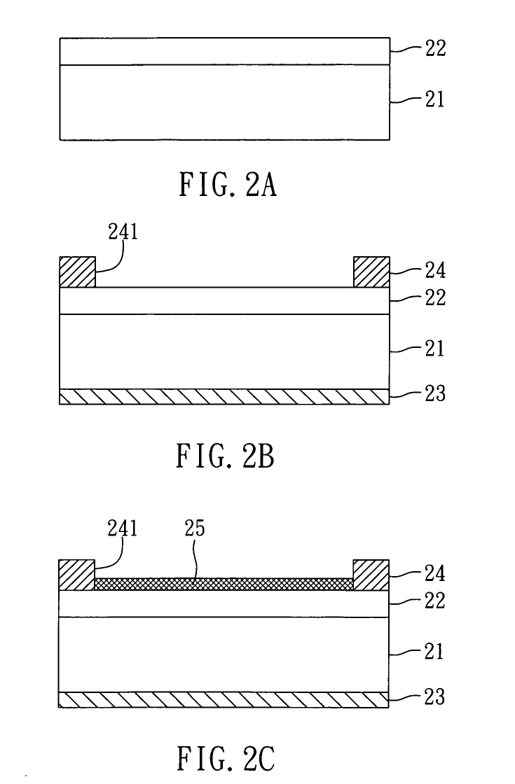

The photovoltaic device of the present invention is the same as that of Embodiment 1, except that the photovoltaic device of the present embodiment further comprises an anti-reflective layer 26 formed on the low reflective conductive film 25, as shown in FIG. 3. Hence, the reflection of the incident light can be reduced; thereby the amount of light extraction can be improved.

### Embodiment 6

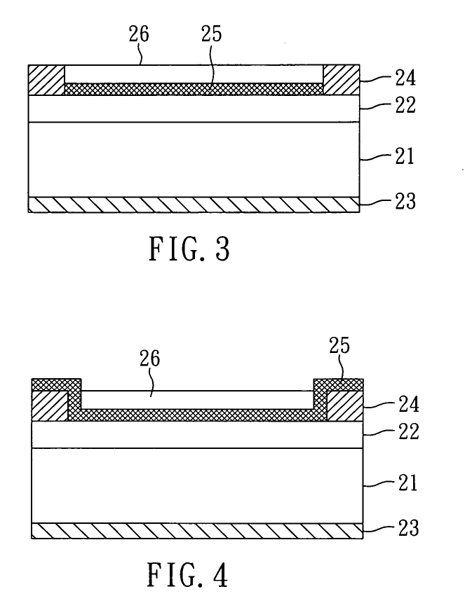

The photovoltaic device of the present invention is the same as that of Embodiment 5, except that the low reflective conductive film 25 of the present embodiment is further formed on the surface of the second electrode layer 24, as shown in FIG. 4.

### Comparative Embodiment 1

The photovoltaic device of the present invention is the same as that of Embodiment 1, except that there is no low reflective conductive film 25 formed in the open area 241 in the photovoltaic device of the present embodiment.

### Comparative Embodiment 2

The photovoltaic device of the present comparative embodiment has the same configuration as the photovoltaic device represented in FIG. 1C. In the present comparative embodiment, the materials and conditions of the p-type semiconductor layer 11, the n-type semiconductor layer 12, the first electrode layer 13, and the second electrode layer 14 are the same as those illustrated in Embodiment 1. In addition, the transparent conductor 16 in the present comparative embodiment is an ITO layer.

### Experiment Example 1

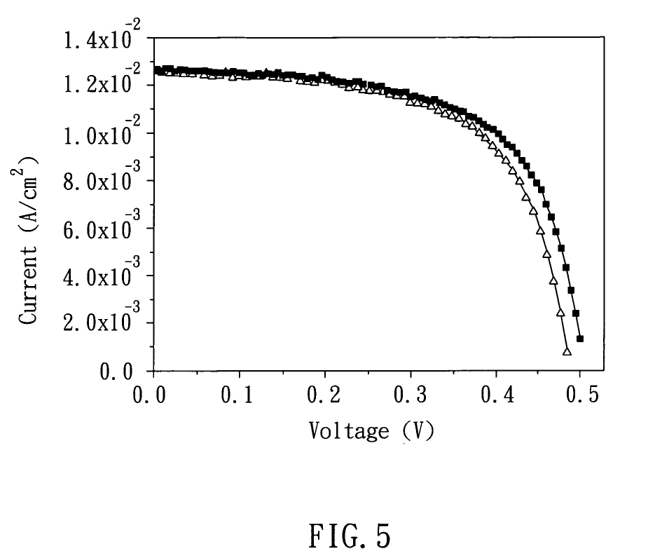

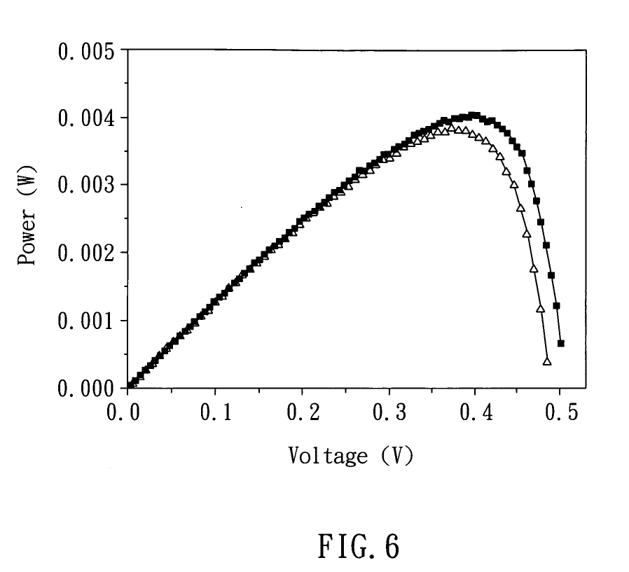

The relation between current and voltage, the relation between voltage and power, and other data about the photoelectric conversion property of the photovoltaic devices prepared by Embodiment 1 and Comparative embodiment 1 are measured in the present experiment example. The testing results are shown in FIGS. 5 and 6, and the following Table 1.

TABLE 1

| | Open circuit | Short circuit | Maximum | | Photoelectric |
|---|---|---|---|---|---|
| | voltage | current | output power | Filling factor | conversion |
| | (V_{oc}, V) | (I_{sc}, A) | (Pₘₐₓ) | (F.F., %) | efficiency (η, %) |
| Comparative | 0.49 | 1.25 × 10⁻² | 3.82 × 10⁻³ | 62.76 | 3.82 |
| embodiment 1 | | | | | |
| Embodiment 1 | 0.501 | 1.27 × 10⁻² | 4.03 × 10⁻³ | 63.43 | 4.03 |

According to the results shown in FIGS. 5 and 6, and Table 1, the photovoltaic device prepared in Embodiment 1 can exhibit better photoelectric conversion property, compared to the photovoltaic device prepared in Comparative embodiment 1. Hence, these results prove that the photoelectric conversion property of the photovoltaic device can be increased effectively by improving the conductivity of the open area of the photovoltaic device.

### Experiment Example 2

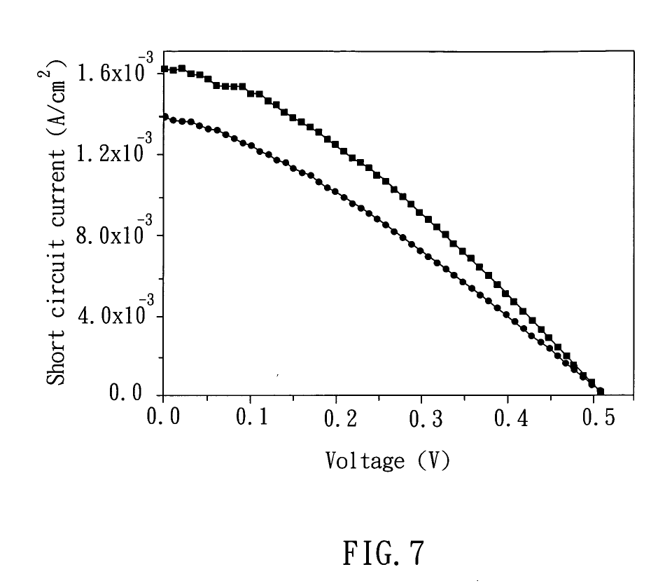

The relation between voltage and short circuit current, and other data about the photoelectric conversion property of the photovoltaic devices prepared by Embodiment 4 and Comparative embodiment 2 are measured in the present experiment example. The testing results are shown in FIG. 7, and the following Table 2.

TABLE 2

| | Open circuit | Short circuit | Maximum | | Photoelectric |
|---|---|---|---|---|---|
| | voltage | current | output power | Filling factor | conversion |
| | (V_{oc}, V) | (I_{sc}, A) | (Pₘₐₓ) | (F.F., %) | efficiency (η, %) |
| Comparative | 0.51 | 1.38 × 10⁻² | 4.22 × 10⁻³ | 31 | 4.22 |
| embodiment 2 | | | | | |
| Embodiment 4 | 0.51 | 1.61 × 10⁻² | 5.6 × 10⁻³ | 34 | 5.6 |

According to the results shown in FIG. 7, and Table 2, the photovoltaic device prepared in Embodiment 4 can exhibit better photoelectric conversion property, compared to the photovoltaic device prepared in Comparative embodiment 2. Compared to the conventional photovoltaic device having a transparent conductor between an electrode and a semiconductor to improve the conductivity, the conductivity of the open area is improved directly by using the photovoltaic device of the present invention. Hence, according to the photovoltaic device of the present invention, the problem of the increase in the interface barrier, which is caused by setting the transparent conductor between the electrode and the semiconductor, can be solved. Thereby, the photoelectric conversion efficiency of the photovoltaic device can be improved more effectively.

Although the present invention has been explained in relation to its preferred embodiment, it is to be understood that many other possible modifications and variations can be made without departing from the scope of the invention as hereinafter claimed.

What is claimed is:

1. A photovoltaic device, comprising:
a first semiconductor layer;
a second semiconductor layer, disposed on the first semiconductor layer;
a first electrode layer, connected to the first semiconductor layer;
a second electrode layer, connected to the second semiconductor layer, wherein the second electrode layer has an open area to expose the second semiconductor layer; and
a low reflective conductive film, disposed in the open area and connected to the second electrode layer and the second semiconductor layer, wherein the resistivity of the low reflective conductive film is less than or equal to that of the second semiconductor layer.

2. The photovoltaic device as claimed in claim 1, further comprising an anti-reflective layer, disposed on the low reflective conductive layer.

3. The photovoltaic device as claimed in claim 1, wherein the low reflective conductive is disposed on a surface of the second electrode layer.

4. The photovoltaic device as claimed in claim 1, wherein the first semiconductor layer is a p-type semiconductor layer, and the second semiconductor layer is an n-type semiconductor layer.

5. The photovoltaic device as claimed in claim 1, wherein the first semiconductor layer is an n-type semiconductor layer, and the second semiconductor layer is a p-type semiconductor layer.

6. The photovoltaic device as claimed in claim 1, wherein the low reflective conductive film is a metal film, a metal oxide film, or a conductive nano-material film.

7. The photovoltaic device as claimed in claim 6, wherein the material of the metal film is the same as the material of the second electrode layer.

8. The photovoltaic device as claimed in claim 6, wherein the metal film is an Al film or an Ag film.

9. The photovoltaic device as claimed in claim 6, wherein the metal oxide film is an ITO film.

10. The photovoltaic device as claimed in claim 6, wherein the conductive nano-material film is a carbon nano-tube film.

11. The photovoltaic device as claimed in claim 1, wherein the second electrode layer is in an interdigitated form.

12. The photovoltaic device as claimed in claim 1, wherein the thickness of the low reflective conductive film is in a range of 10 Å to 10 μm.

13. The photovoltaic device as claimed in claim 1, wherein the resistivity of the low reflective conductive film is in a range of 10⁻³ Ωcm to 10⁻⁸ Ωcm.

14. The photovoltaic device as claimed in claim 1, wherein the reflectivity of the low reflective conductive film is less than 10%.

15. A method for manufacturing a photovoltaic device, comprising following steps:
forming a second semiconductor layer on a first semiconductor layer;
forming a first electrode layer on the first semiconductor layer, and forming a second electrode layer on the second semiconductor layer, wherein the second electrode layer has an open area to expose the second conductor layer; and
forming a low reflective conductive film in the open area, to connect the low reflective conductive film to the second electrode layer and the second semiconductor layer, wherein the resistivity of the low reflective conductive film is less than or equal to that of the second semiconductor layer.

16. The method as claimed in claim 15, further comprising a step of: forming an anti-reflective layer on the low reflective conductive film.

17. The method as claimed in claim 15, wherein the low reflective conductive film further forms on a surface of the second electrode layer.

18. The method as claimed in claim 15, wherein the first semiconductor layer is a p-type semiconductor layer, and the second semiconductor layer is an n-type semiconductor layer.

19. The method as claimed in claim 15, wherein the first semiconductor layer is an n-type semiconductor layer, and the second semiconductor layer is a p-type semiconductor layer.

20. The method as claimed in claim 15, wherein the low reflective conductive film is a metal film, a metal oxide film, or a conductive nano-material film.

21. The method as claimed in claim 20, wherein the material of the metal film is the same as the material of the second electrode layer.

22. The method as claimed in claim 20, wherein the metal film is an Al film or an Ag film.

23. The method as claimed in claim 20, wherein the metal oxide film is an ITO film.

24. The method as claimed in claim 20, wherein the conductive nano-material film is a carbon nano-tube film.

25. The method as claimed in claim 15, wherein the second electrode layer is in an interdigitated form.

26. The method as claimed in claim 15, wherein the thickness of the low reflective conductive film is in a range of 10 Å to 10 μm.

27. The method as claimed in claim 15, wherein the resistivity of the low reflective conductive film is in a range of 10⁻³ Ωcm to 10⁻⁸ Ωcm.

28. The method as claimed in claim 15, wherein the reflectivity of the low reflective conductive film is less than 10%.
